(19) United States
(12) Patent Application Publication
(10) Pub. No.: US 2002/0062971 A1
(43) Pub. Date: May 30, 2002

(54) Ultra-thin-film package

(76) Inventor: Wen Lo Shieh, Kaohsiung City (TW)

Correspondence Address: Wen Lo SHIEH, PO Box 82-144, TAIPEI, TW

(21) Appl. No.: 09/834,939

(22) Filed: Apr. 16, 2001

(30) Foreign Application Priority Data
Nov. 27, 2000 (TW) 089125423

(51) Int. Cl. H05K 1/03

(52) U.S. Cl. 174/52.4

(57) ABSTRACT

An ultra-thin film package, characterized in that polymeric film die carrier (or substrate) or polyimide (PI) die carrier (or substrate) is employed, and the leg position for die bonding is made into a recess shape to lower the thickness after bonding, and polymeric film die carrier (or substrate) or PI die carrier (or substrate) is made into a thin film shape by a fabrication technique (chemical etching or laser fabrication method), and the I/O leg position is made into a recess shape and the die is glued to the polymeric film die carrier (or substrate) or PI die carrier (or substrate) and then changed with a package material. By means of a dicing step, a single package granule containing dies is cut, wherein polymeric film die carrier (or substrate) or PI die carrier (or substrate) and the die are soldered at one end of a wire, the other end is mounted with a metal pad within the leg position which is recessed on the polymeric die film carrier (or substrate) or PI die carrier (or substrate), and the electrode of the metal pad is protruded from the back face of the polymeric film die carrier (or substrate) or PI die carrier (or substrate).

### BACKGROUND OF THE INVENTION

(a) Technical Field of the Invention

The present invention relates to an ultra-thin-film package, and in particular, a package employing polymeric film or polyimide (PI) layer to form die carrier (or substrate), and employing the designed properties of ultra-thin and high density of the polymeric film or PI die carrier in a package, so that the thickness of the entire package is greatly reduced.

(b) Description of the Prior Art

The latest trend of film packages are directed to being light, thin, short, and of small size. In order to attain the above functions and objects, the layout density of the semiconductor has to be improved so as to reduce the size of the die in association with the carrier holding the dies to provide high density leg distance and ultra thin property, so that the real thin, light, short and small package module can be obtained.

In conventional ultra-thin package techniques, such as the micro lead frame package technique, as shown in FIG. 1a, the bottom section of the lead frame 12′ is adhered to with heat resistant tape 11′ and the lead frame 12′ is adhered to with die 13′ and the wire bonding method is used to electrically bond the wire 14′ with the bonding key 15′ of the lead frame 12′ such that the structure carrying the die 13′ makes use of the lead frame 12′. The lead frame 12′ is thin plate made from iron, nickel alloy or copper alloy, and chemicals are used in the etching process to erode the unwanted portion. However, due to the restriction of the thickness of the lead frame 12′, and the minimum thickness of the bonding formed after dicing by the lead frame 12′, and the gap between each bonding, very thin sized die cannot be obtained. If the thickness of the die 13′ on the lead frame 12′ and the height of the wire 14′ for electrical connection, are together with the thickness of the package material 16′ (molding compound) for protection of various components, the thickness of the entire package module cannot be reduced. Thus, even if the development of die has become very small and thin, the drawback of the lead frame 12′ cannot be overcome. Referring to FIGS. 1b and 2, after the package material 16′ is changed, it is diced into a single package granule with a flat bottom, however it has the problem of bonding the PCB with the package granule and the adhesion of the solder.

Accordingly, it is a main object of the present invention to provide an ultra-thin film package which can mitigate the above drawback.

### SUMMARY OF THE INVENTION

Accordingly, it is an object of the present invention to provide an ultra-thin film package, wherein the entire thickness of the package is effectively lowered.

Yet another object of the present invention is to provide an ultra-thin film package, wherein the electrode at the bottom section of the single package granule is protruded to be appropriately used for adhesion operation, and the solder bonding point of the PCB is used for soldering function.

A further object of the present invention is to provide a ultra-thin film package, characterized in that polymeric film die carrier (or substrate) or polyimide (PI) die carrier (or substrate) is employed, and the leg position for die bonding is made into a recess shape to lower the thickness after bonding, and polymeric film die carrier (or substrate) or PI die carrier (or substrate) is made into thin film shape by a fabrication technique (chemical etching or laser fabrication method), and the I/O leg position is made into a recess shape and the die is glued to the polymeric film die carrier (or substrate) or PI die carrier (or substrate) and then changed with a package material. By means of a dicing step, a single package granule containing dies is cut, wherein polymeric film die carrier (or substrate) or PI die carrier (or substrate) and the die are soldered at one end of a wire, the other end is mounted with a metal pad within the leg position which is recessed on the polymeric die film carrier (or substrate) or PI die carrier (or substrate), and the electrode of the metal pad is protruded from the back face of the polymeric film die carrier (or substrate) or PI die carrier (or substrate).

Yet another object of the present invention is to provide an ultra-thin film package, wherein the I/O bump is mounted within the recessed leg position on the polymeric film or PI die carrier or substrate which effectively reduces the entire package thickness.

### BRIEF DESCRIION OF THE DRAWINGS

FIG. 1a is a sectional view of a conventional ultra-thin film package.

FIG. 1b is a sectional view of a single package die of a conventional ultra-thin film package.

FIG. 2 is a schematic view of the lead frame of the conventional ultra-thin film package technology.

FIG. 3a is a sectional view of the bonding of the polymeric film die carrier (or substrate) or PI die carrier (or substrate) with the die of the present invention.

FIG. 3b is a schematic view of the solder connection point of the PCB and the single package die of the present invention.

FIG. 4 is a schematic view of the carrier top face of the polymeric film die carrier (or substrate) or PI die carrier (or substrate) with the die of the present invention.

FIG. 5 is another preferred embodiment of the present invention.

FIG. 6 is a die bonding method of the preferred embodiment of the present invention.

FIG. 7 is a die bonding method of another preferred embodiment of the present invention.

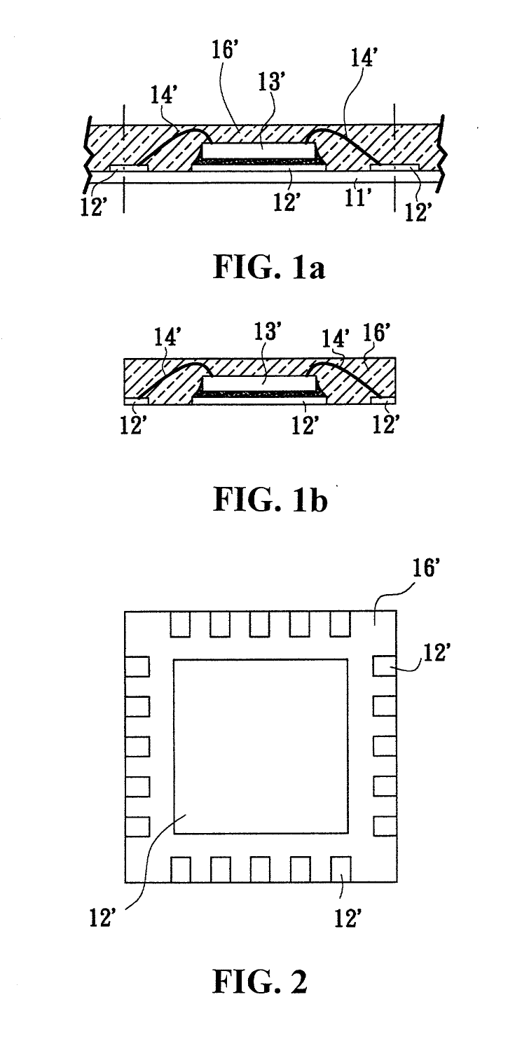

### DETAILED DESCRIPTION OF THE PREFERRED EMBODIMENT

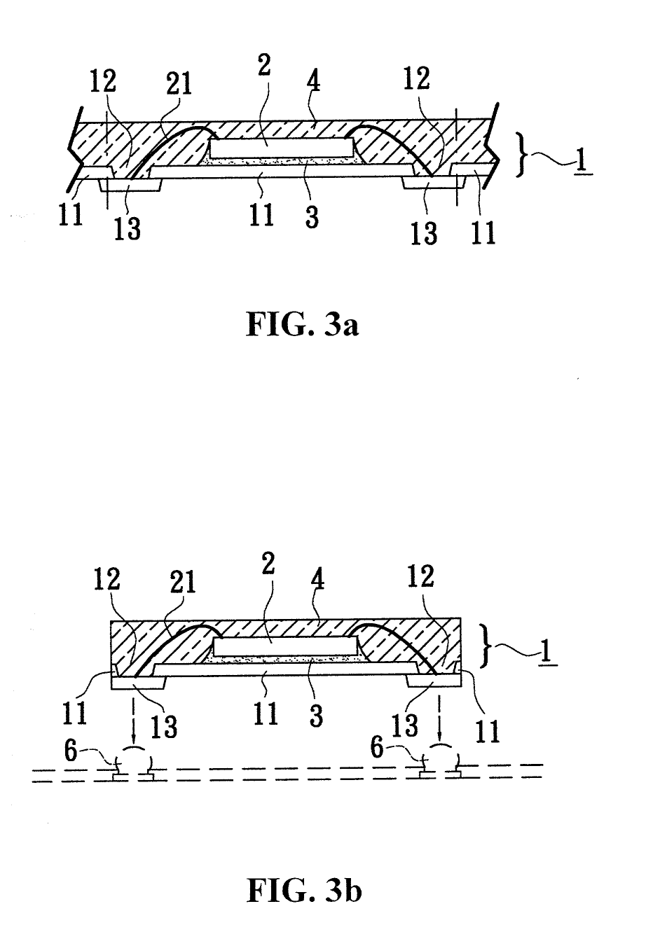

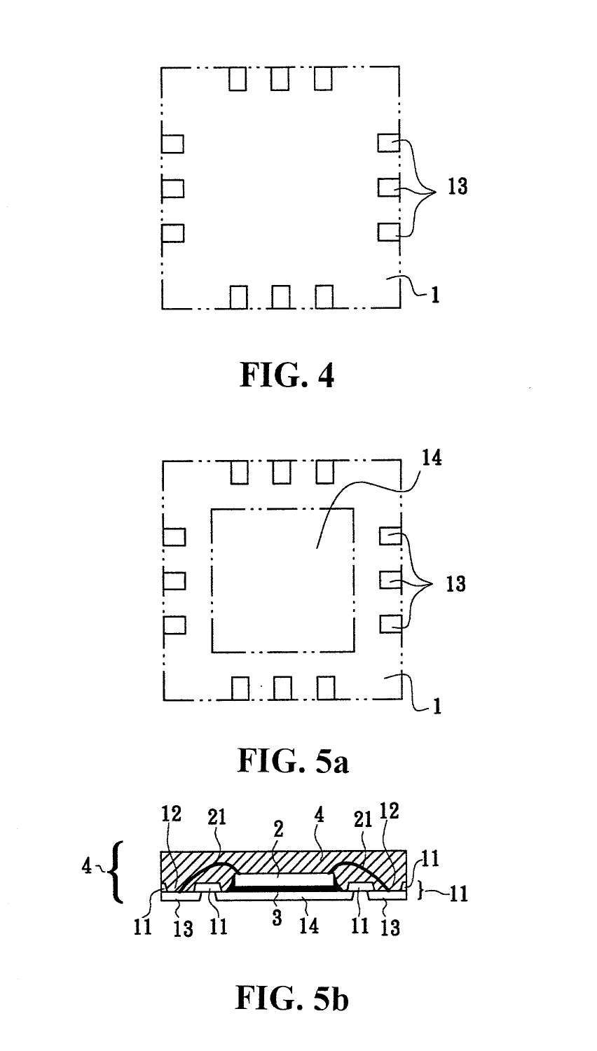

Referring to FIGS. 3a, 3b and FIG. 4, there is shown an ultra-thin film package, employing polymeric film or polyimide (PI) layer to make die carrier, and the leg position for bonding with the die is made into a recess such that one end of the wire of the bonding die is introduced into the recessed leg position so as to reduce the bonding thickness between the polymeric film or PI die carrier (or substrate) with die by means of package technique.

In accordance with the present invention, the polymeric film or PI layer 11 is used as polymeric film die carrier (or substrate) or PI die carrier (or substrate) 1 and with matrix mode to carry the dies 2, and by substrate-fabrication technique (chemical etching or laser fabrication method) the PI die carrier 1 is made into very thin film, and the I/O leg position 12 is made into a recess shape. The die 2 is glued onto the polymeric film or PI die carrier (or substrate) by adhesive 3.

At the electrically connected section, wire bonding technique is used to adhere one end of the wire 21 onto the die 2 and the other end is introduced into the metal pad 13 within the recessed leg position 12 provided on the polymeric film or PI die carrier (or substrate) 1. After that, a package material 4 is introduced to protect the die 2 and the wire 21. Finally, a single die package granule containing die 2 is diced to form a package unit.

Referring to FIG. 5, on the polymeric film die carrier (or substrate) or PI die carrier (or substrate), corresponding to the back face position of the die 2, a metal plate 14 is adhered, which will effectively increase heat dissipation of die 2.

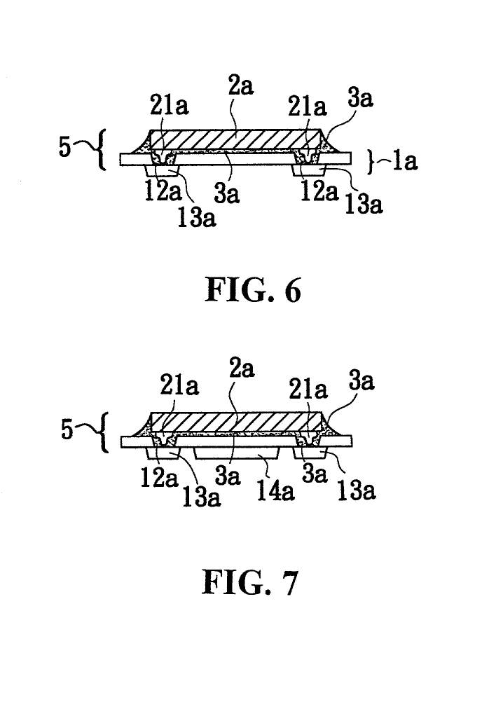

In accordance with the present invention, the electrical connection technique of the die with the polymeric film die carrier (or substrate) or PI die carrier (or substrate) can be a die bonding method, as shown in FIG. 6, where there is shown the die bonding method in accordance with the present invention. The polymeric film die carrier (or substrate) or PI die carrier (or substrate) 1a is provided with a recessed leg position 12a for bonding with die 2a, and after that, the die 2a is reversed such that the I/O bump 21a of the die 2a is bonded with the metal pad 13a on the leg position 12a of the polymeric thin die carrier (or substrate) or PI die carrier (or substrate) 1a. At the bonding gap between the die 2a and the polymeric film die carrier (or substrate) 1a, glue 3a is filled to increase its bonding and to oppose dispersion stress.

Referring to FIG. 7, a metal pad 14a is provided at the polymeric film die carrier (or substrate) or PI die carrier (or substrate) 1a, corresponding to the back face of the die 2a, so as to effectively increase the heat dissipation of the die 2a.

In accordance with the present invention, polymeric film or PI (polyimide) layer is used to fabricate a die carrier. Thus, polymeric thin die carrier (or substrate) or PI die carrier (or substrate) can be fabricated into very thin film and the bonding leg position of the die wire (or die bump) is made into a recess shape, the height of the wire bonding is also reduced. If the die bonding technique is employed, the thickness can be reduced and at the same time the package area is reduced and an ultra-fine or ultra-thin package module can be fabricated.

In accordance with the present invention, the electrode (metal pad) at the bottom side of the single package granule containing die is protruded. This will facilitate soldering alignment of the package granule with the solder 6 on the PCB and this provides a better soldering function, and thus, the manufacturing process is improved.

While the invention has been described with respect to preferred embodiments, it will be clear to those skilled in the art that modifications and improvements may be made to the invention without departing from the spirit and scope of the invention. Therefore, the invention is not to be limited by the specific illustrative embodiment, but only by the scope of the appended claims.

We claim:

1. An ultra-thin film package, characterized in that polymeric film die carrier (or substrate) or polyimide (PI) die carrier (or substrate) is employed, and the leg position for die bonding is made into a recess shape to lower the thickness after bonding, and polymeric film die carrier (or substrate) or PI die carrier (or substrate) is made into a thin film shape by a fabrication technique (chemical etching or laser fabrication method), and the I/O leg position is made into a recess shape and the die is glued to the polymeric film die carrier (or substrate) or PI die carrier (or substrate) and then changed with a package material. By means of a dicing step, a single package granule containing dies is cut, wherein polymeric film die carrier (or substrate) or PI die carrier (or substrate) and the die are soldered at one end of a wire, the other end is mounted with a metal pad within the leg position which is recessed on the polymeric die film carrier (or substrate) or PI die carrier (or substrate), and the electrode of the metal pad is protruded from the back face of the polymeric film die carrier (or substrate) or PI die carrier (or substrate).

2. An ultra-thin film package as set forth in claim 1, wherein a metal plate is provided at the polymeric film die carrier (or substrate) or PI die carrier (or substrate), corresponding to the back face of the die position.

3. An ultra-thin film package as set forth in claim 1, wherein the electrical bonding of the die with polymeric film die carrier (or substrate) or PI die carrier (or substrate) is a die bonding method such that the I/O bump of the die and the metal pad on the leg position of the polymeric film die carrier (or substrate) or PI die carrier (or substrate) are bonded.

4. An ultra-thin film package as set forth in claim 3, wherein a metal plate is provided at the polymeric film die carrier (or substrate) or PI die carrier (or substrate), corresponding to the back face of the die position.
